(19) United States
(12) Patent Application Publication
(10) Pub. No.: US 2024/0030313 A1
(43) Pub. Date: Jan. 25, 2024

(54) DEVICE HAVING FERROELECTRIC OR NEGATIVE CAPACITANCE MATERIAL AND METHOD OF MANUFACTURING THE SAME, AND ELECTRONIC APPARATUS

(71) Applicant: INSTITUTE OF MICROELECTRONICS, CHINESE ACADEMY OF SCIENCES, Chaoyang District, Beijing (CN)

(72) Inventors: Huilong ZHU, Poughkeepsie, NY (US); Weixing HUANG, BEIJING (CN)

(73) Assignee: INSTITUTE OF MICROELECTRONICS, CHINESE ACADEMY OF SCIENCES, Chaoyang District, Beijing (CN)

(21) Appl. No.: 18/025,030

(22) PCT Filed: Mar. 24, 2021
(86) PCT No.: PCT/CN2021/082732

§ 371 Date: Mar. 7, 2023

(30) Foreign Application Priority Data
Sep. 7, 2020 (CN) 202010932029.9

(51) Int. Cl. H01L 29/66; H01L 29/06; H01L 29/786; H01L 29/775; H01L 29/423; H01L 27/088; H01L 21/8234; H01L 29/51

(52) U.S. Cl. CPC H01L 29/6656; H01L 29/0673; H01L 29/78696; H01L 29/775; H01L 29/42392; H01L 29/66545; H01L 27/088; H01L 21/823412; H01L 21/823468; H01L 21/823481; H01L 29/516

(57) ABSTRACT

A nanowire/nanosheet device having a ferroelectric or negative capacitance material and a method of manufacturing the same, and an electronic apparatus including the nanowire/nanosheet device are provided. According to embodiments, the semiconductor device may include: a substrate; a nanowire/nanosheet on the substrate and spaced apart from a surface of the substrate; a gate electrode surrounding the nanowire/nanosheet; a ferroelectric or negative capacitance material layer formed on a sidewall of the gate electrode; and source/drain layers at opposite ends of the nanowire/nanosheet and adjoining the nanowire/nanosheet.

### CROSS REFERENCE TO RELATED APPLICATION(S)

This application is a Section 371 National Stage Application of International Application No. PCT/CN2021/082732, filed on Mar. 24, 2021, which claims priority to Chinese Patent Application No. 202010932029.9 entitled “DEVICE HAVING FERROELECTRIC OR NEGATIVE CAPACITANCE MATERIAL AND METHOD OF MANUFACTURING THE SAME, AND ELECTRONIC APPARATUS” filed on Sep. 7, 2020, the content of which is incorporated herein in its entirety by reference.

### TECHNICAL FIELD

The present disclosure relates to a field of a semiconductor technology, and in particular, to a nanowire/nanosheet device having a ferroelectric or negative capacitance material, a method of manufacturing the nanowire/nanosheet device, and an electronic apparatus including the nanowire/nanosheet device.

### BACKGROUND

A nanowire or nanosheet (hereinafter referred to as “nanowire/nanosheet”) device, especially a nanowire/nanosheet-based Gate-All-Around (GAA) Metal Oxide Semiconductor Field Effect Transistor (MOSFET), may control a short channel effect well and achieve a further miniaturization of the device. However, with an increasing miniaturization, a spacing between components becomes smaller and smaller, which may increase a proportion of overlapping capacitances between the components in a total capacitance of the device. It is desirable to reduce the overlapping capacitances, especially a capacitance between a bottom substrate and a gate below the nanowire/nanosheet.

### SUMMARY

In view of this, an objective of the present disclosure is, at least in part, to provide a nanowire/nanosheet device having a ferroelectric or negative capacitance material, a method of manufacturing the nanowire/nanosheet device, and an electronic apparatus including the nanowire/nanosheet device.

According to an aspect of the present disclosure, a nanowire/nanosheet device is provided, including: a substrate; a nanowire/nanosheet on the substrate and spaced apart from a surface of the substrate; a gate electrode surrounding the nanowire/nanosheet; a ferroelectric or negative capacitance material layer formed on a sidewall of the gate electrode; and source/drain layers at opposite ends of the nanowire/nanosheet and adjoining the nanowire/nanosheet.

According to another aspect of the present disclosure, a method of manufacturing a nanowire/nanosheet device is provided, including: providing, on a substrate, a nanowire/nanosheet spaced apart from a surface of the substrate; forming, on the substrate, a dummy gate surrounding the nanowire/nanosheet; forming a spacer on a sidewall of the dummy gate by using a ferroelectric or negative capacitance material; and removing the dummy gate, and forming, on an inner side of the spacer, a gate electrode in a gate trench formed by a removal of the dummy gate.

According to another aspect of the present disclosure, a method of manufacturing a nanowire/nanosheet device is provided, including: providing, on a substrate, a nanowire/nanosheet spaced apart from a surface of the substrate; forming, on the substrate, a dummy gate surrounding the nanowire/nanosheet; forming a spacer on a sidewall of the dummy gate; removing the dummy gate, and forming, on an inner side of the spacer, a ferroelectric or negative capacitance material layer in a gate trench formed by a removal of the dummy gate; and forming a gate electrode in the gate trench formed with the ferroelectric or negative capacitance material layer.

According to another aspect of the present disclosure, an electronic apparatus is provided, including the nanowire/nanosheet device as described above.

According to embodiments of the present disclosure, the ferroelectric or negative capacitance material layer is provided on the sidewall of the gate electrode. The ferroelectric or negative capacitance material layer may be in a form of a spacer. Device characteristics, such as a threshold voltage (Vt), a Drain Induced Barrier Lowering (DIBL), a Subthreshold Swing (SS), etc., may be easily adjusted by adjusting a material of the ferroelectric or negative capacitance material layer.

### BRIEF DESCRIPTION OF THE DRAWINGS

The above and other objectives, features, and advantages of the present disclosure will be clearer through the following descriptions of embodiments of the present disclosure with reference to accompanying drawings, wherein:

FIG. 1 to FIG. 18(b) schematically show some stages in a process of manufacturing a nanowire/nanosheet device according to embodiments of the present disclosure, and

wherein FIG. 1, FIG. 3(a), FIG. 4(a), FIG. 5(b), FIG. 6, FIG. 7(a), FIG. 7(b), FIG. 8(a), FIG. 9(a), FIG. 9(b), FIG. 10, FIG. 11(a), FIG. 12(a), FIG. 13(a), FIG. 14(a), FIG. 15(a), FIG. 16(a), FIG. 17(a) and FIG. 18(a) are cross-sectional views taken along line AA′,

FIG. 3(b), FIG. 4(b), FIG. 8(b), FIG. 11(b), FIG. 12(b), FIG. 13(b), FIG. 14(b), FIG. 15(b), FIG. 16(b), FIG. 17(b) and FIG. 18(b) are cross-sectional views taken along line BB′, and

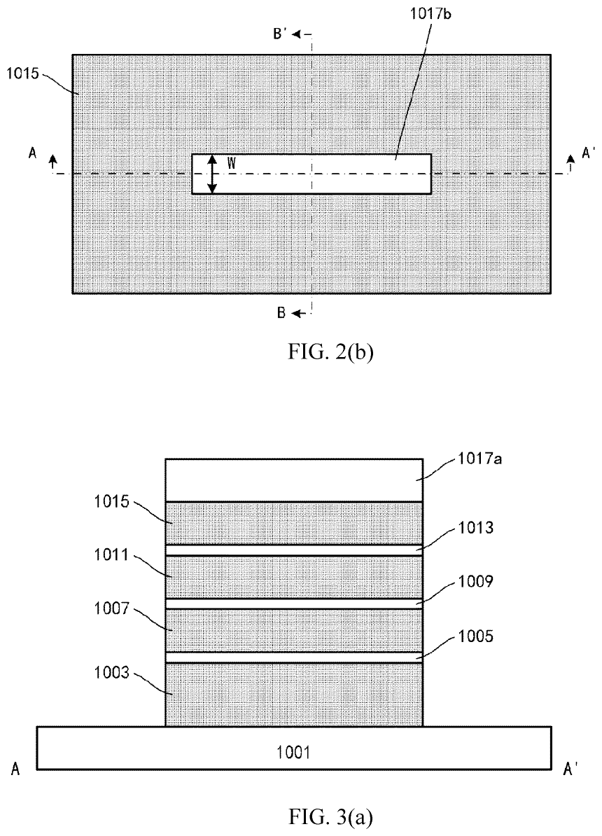

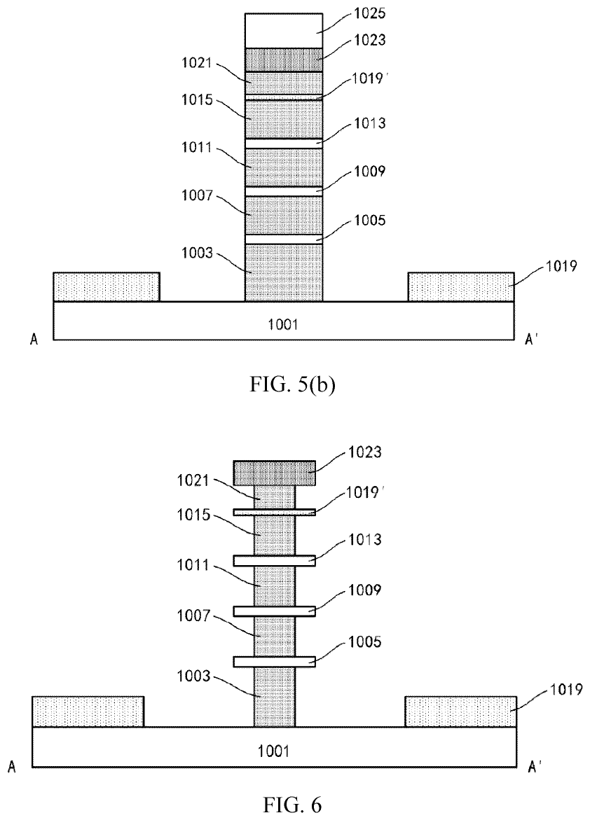

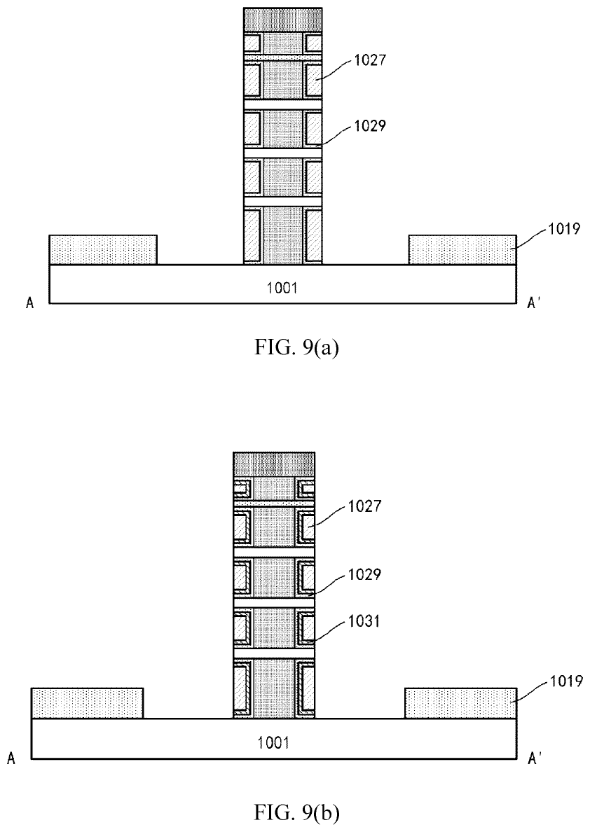

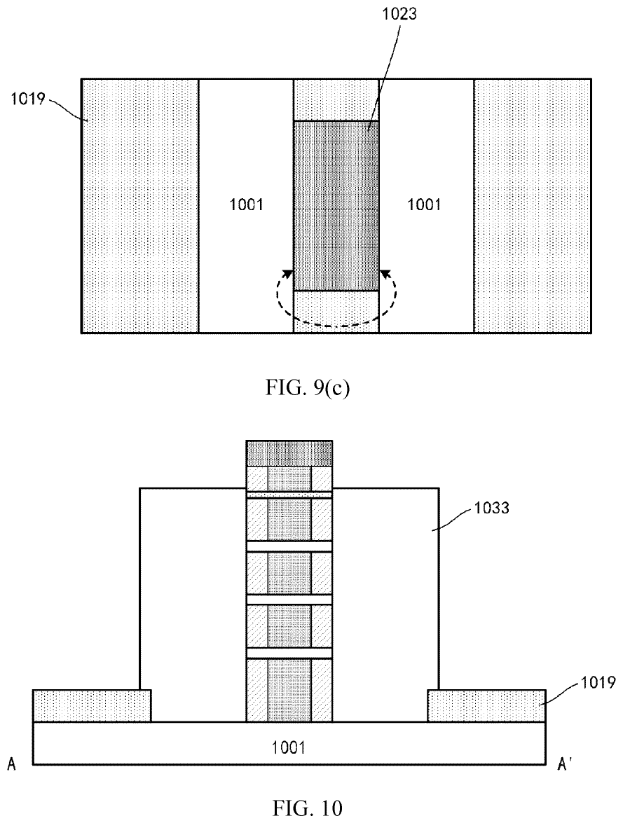

FIG. 2(a), FIG. 2(b), FIG. 5(a) and FIG. 9(c) are top views, and positions of lines AA′ and BB′ are shown in FIG. 2(a).

### DETAILED DESCRIPTION OF EMBODIMENTS

Embodiments of the present disclosure will be described below with reference to accompanying drawings. However, it should be understood that these descriptions are only exemplary, and are not intended to define the scope of the present disclosure. Moreover, in the following descriptions, descriptions of well-known structures and technologies are omitted to avoid unnecessarily obscuring the concept of the present disclosure.

Various schematic structural diagrams according to embodiments of the present disclosure are shown in the accompanying drawings. The drawings are not drawn to scale. Some details are enlarged and some details may be omitted for clarity of presentation. Shapes of the various regions, layers and a relative size and a positional relationship thereof shown in the drawings are only exemplary. In practice, there may be deviations due to manufacturing tolerances or technical limitations, and those skilled in the art may additionally design regions/layers with different shapes, sizes, and relative positions according to actual needs.

In the context of the present disclosure, when a layer/element is referred to as being located “on” another layer/element, the layer/element may be directly on the another layer/element, or there may be an intermediate layer/element therebetween. In addition, if a layer/element is located “on” another layer/element in one orientation, the layer/element may be located “under” the another layer/element when the orientation is reversed.

According to embodiments of the present disclosure, a nanowire/nanosheet device is provided. Specifically, the device may include at least one nanowire or nanosheet (referred to simply as “nanowire/nanosheet”) to be used as a channel. The nanowire/nanosheet may be suspended relative to a substrate and may extend substantially parallel to a surface of the substrate. Nanowires/nanosheets may be aligned with each other in a vertical direction (e.g., a direction substantially perpendicular to the surface of the substrate). The nanowire/nanosheet may extend in a first direction, and may adjoin source/drain layers at opposite ends of the nanowire/nanosheet in the first direction. The source/drain layer may include a semiconductor material different from that of the nanowire/nanosheet to achieve stress engineering. In addition, a gate electrode may intersect each nanowire/nanosheet in a second direction intersecting (e.g., perpendicular to) the first direction, and thus may surround a periphery of each nanowire/nanosheet, so that a Gate-All-Around (GAA) structure may be formed.

According to embodiments of the present disclosure, a ferroelectric or negative capacitance material layer may be provided on a sidewall of the gate electrode. The ferroelectric material is generally in one of two polarization states, such as an upward polarization or a downward polarization. However, under some special conditions (a special matching of capacitances), the ferroelectric material may be stabilized between the two polarization states, that is, the so-called negative capacitance state. According to different states of a ferroelectric or negative capacitance material, the device may have different performances, such as a threshold voltage (Vt), a Drain Induced Barrier Lowering (DIBL), a Subthreshold Swing (SS), etc. When the ferroelectric or negative capacitance material is in the negative capacitance state, a negative capacitance may be introduced between the gate electrode and the source/drain, and even a total capacitance between the gate and the source/drain may be less than zero (which may lead to SS of less than 60 mV/dec at 300K). Thus, an overall capacitance of the semiconductor device may be reduced.

The ferroelectric or negative capacitance material layer may be in a form of a spacer. For example, the spacer may be formed on a dummy gate, so that a gate trench used to form the gate electrode may be defined after removing the dummy gate. A gate dielectric layer and the gate electrode may be formed in the gate trench.

That is, the ferroelectric or negative capacitance material layer in the form of the spacer may be a gate spacer of the device, and may extend along substantially an entire height of the sidewall of the gate electrode. The so-called “substantially an entire height” or “main portion of a height” used herein may mean that except for a height of a small portion occupied by a margin to be considered due to a process fluctuation or some residues in other steps, a height of a remaining portion is occupied by the gate spacer.

Alternatively, the ferroelectric or negative capacitance material layer may continuously extend on the sidewall of the gate electrode and a bottom surface of the gate electrode. In the case, the ferroelectric or negative capacitance material layer may be formed in a gate trench defined by a removal of the dummy gate (a sidewall thereof may be formed with a spacer including the ferroelectric or negative capacitance material). For example, the ferroelectric or negative capacitance material layer may be formed between the gate dielectric layer and the gate electrode, or between an inner wall of the gate trench and the gate dielectric layer.

In addition, a potential equalization layer may be introduced to equalize a potential on a surface of the gate electrode. For example, the potential equalization layer may be arranged between the gate dielectric layer and the ferroelectric or negative capacitance material layer.

Such a semiconductor device may be manufactured as follows, for example. A nanowire/nanosheet spaced apart from a surface of the substrate may be provided on the substrate, and a dummy gate surrounding the nanowire/nanosheet may be formed. A dummy gate spacer may be formed on a sidewall of the dummy gate. The dummy gate spacer may be a single-layer or multi-layer configuration, at least one layer of which may be a ferroelectric or negative capacitance material layer. The dummy gate may be removed to form a gate trench inside the dummy gate spacer. The ferroelectric or negative capacitance material layer (which may be omitted in a case that the dummy gate spacer includes the ferroelectric or negative capacitance material layer) and a gate electrode may be formed in the gate trench. In addition, in the gate trench, a potential equalization layer may further be formed between a gate dielectric layer and the ferroelectric or negative capacitance material layer.

The present disclosure may be presented in various forms, some examples of which will be described below. In the following descriptions, a selection of various materials is involved. In the selection of the material, in addition to a function of the material (for example, a semiconductor material may be used for forming an active region, and a dielectric material may be used for forming an electrical isolation), an etching selectivity is also considered. In the following descriptions, a required etching selectivity may or may not be indicated. It should be clear to those skilled in the art that when etching a material layer is mentioned below, if it is not mentioned or shown that other layers are also etched, then the etching may be selective, and the material layer may have etching selectivity relative to other layers exposed to the same etching formula.

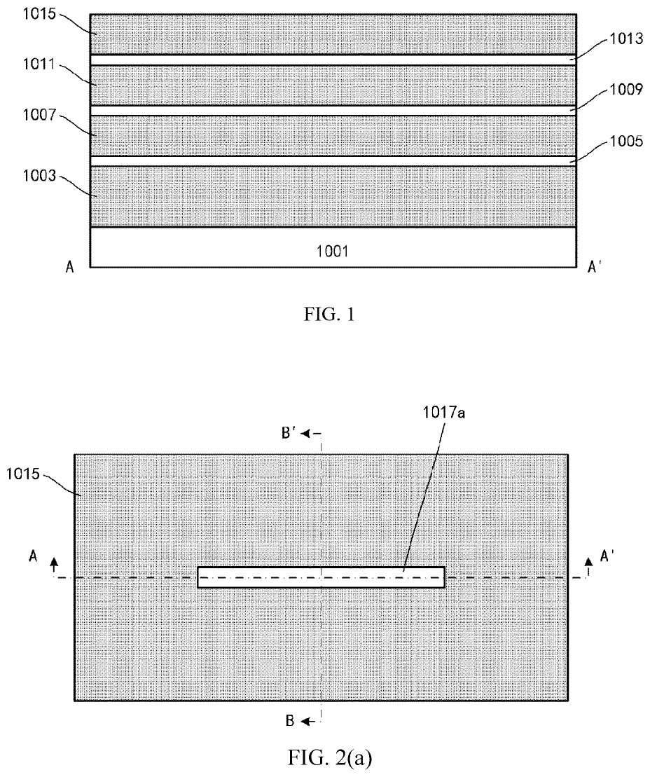

FIG. 1 to FIG. 18(b) schematically show some stages in a process of manufacturing a semiconductor device according to embodiments of the present disclosure.

As shown in FIG. 1, a substrate 1001 is provided. The substrate 1001 may be in various forms, including but not limited to a bulk semiconductor material substrate such as a bulk Si substrate, a semiconductor-on-insulator (SOI) substrate, a compound semiconductor substrate such as a SiGe substrate, and the like. In the following descriptions, for ease of explanation, a bulk Si substrate is taken as an example for description. Here, a silicon wafer is provided as the substrate 1001.

An isolation portion defining layer 1003 may be formed on the substrate 1001 to define a position of an isolation portion to be formed subsequently. An etch stop layer 1005 may be formed on the isolation portion defining layer 1003. The etch stop layer 1005 may be used to define a stop position when etching the isolation portion defining layer 1003 subsequently, especially no etching selectivity or a low etching selectivity exists between the isolation portion defining layer 1003 and a gate defining layer (e.g., 1007) subsequently formed. Alternatively, the etch stop layer 1005 may be omitted in a case that the etching selectivity exists between the isolation portion defining layer 1003 and the gate defining layer subsequently formed.

A stack of gate defining layers 1007, 1011, 1015 and nanowire/nanosheet defining layers 1009, 1013 may be arranged alternately on the etch stop layer 1005. The gate defining layers 1007, 1011, 1015 may define a position of a gate stack to be formed subsequently, and the nanowire/nanosheet defining layers 1009, 1013 may define a position of a nanowire/nanosheet to be formed subsequently. In the stack, an uppermost layer may be the gate defining layer 1015, so that each of the nanowire/nanosheet defining layers 1009, 1013 is covered above and below by the gate defining layers, so as to subsequently form a gate-all-around configuration. In the example, two nanowire/nanosheet defining layers 1009, 1013 may be formed, and thus two nanowires/nanosheets are formed in a final device. However, the present disclosure is not limited to this. The number of nanowire/nanosheet defining layers to be formed may be determined according to the number (which may be one or more) of nanowires/nanosheets to be finally formed, and the number of gate defining layers to be formed may be determined accordingly.

The isolation portion defining layer 1003, the etch stop layer 1005, the gate defining layers 1007, 1011, 1015, and the nanowire/nanosheet defining layers 1009, 1013 may be semiconductor layers formed on the substrate 1001 by, for example, an epitaxial growth. Therefore, the nanowire/nanosheet defining layers 1009, 1013 may have a good crystal quality and may be of a single crystal structure, so as to subsequently provide a single crystal nanowire/nanosheet for use as a channel. Adjacent semiconductor layers among the semiconductor layers may have etching selectivity to each other, so as to be subsequently processed separately. For example, the etch stop layer 1005 and the nanowire/nanosheet defining layers 1009, 1013 may include Si, and the isolation portion defining layer 1003 and the gate defining layers 1007, 1011, 1015 may include SiGe (the atomic percentage of Ge is in a range of, for example, about 10% to 40%, and may be gradually changed to reduce defectivity). Each semiconductor layer may have a substantially uniform thickness, so as to extend substantially parallel to a surface of the substrate 1001. For example, a thickness of the isolation portion defining layer 1003 may be in a range of about 30 nm to 80 nm, a thickness of the etch stop layer 1005 may be in a range of about 3 nm to 15 nm, a thickness of the gate defining layers 1007, 1011, 1015 may be in a range of about 20 nm to 40 nm, and a thickness of the nanowire/nanosheet defining layers 1009, 1013 may be in a range of about 5 nm to 15 nm.

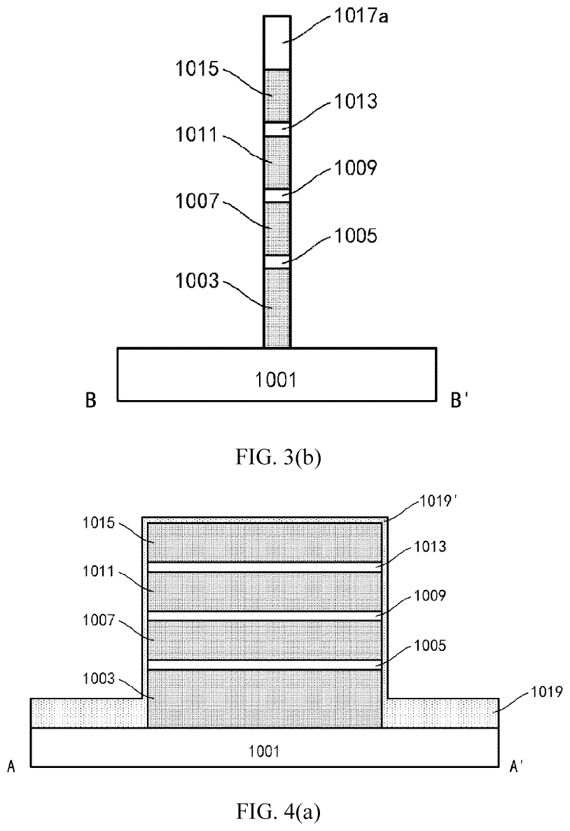

Next, the nanowire/nanosheet may be patterned. For example, as shown in FIG. 2(a) and FIG. 2(b), a mask such as a photoresist 1017a or 1017b may be formed on the above-mentioned stack, and the photoresist 1017a or 1017b may be patterned into a form of a nanowire (FIG. 2(a)) or nanosheet (FIG. 2(b)) by photolithography. For the nanosheet, a width W of the nanosheet may determine a device width with which the device provides a current. In the following descriptions, the nanowire is mainly taken as an example, and the descriptions may also be applied to the nanosheet. Then, as shown in FIG. 3(a) and FIG. 3(b), various layers on the substrate 1001 may be selectively etched sequentially by, for example, Reactive Ion Etching (RIE), with the photoresist 1017a or 1017b as a mask, and the etching may stop at the substrate 1001. In this way, the layers on the substrate 1001 are patterned as a preliminary nanowire or nanosheet corresponding to the photoresist 1017a or 1017b. Here, a length (a longitudinal dimension, that is, a length in a horizontal direction in an orientation shown in FIG. 3(a)) of the preliminary nanowire/nanosheet may be less than a length of a nanowire/nanosheet to be formed for use as a channel, so that the nanowire/nanosheet self-aligned with the dummy gate (gate stack) may be subsequently obtained to be used as a channel. After that, the photoresist 1017a or 1017b may be removed.

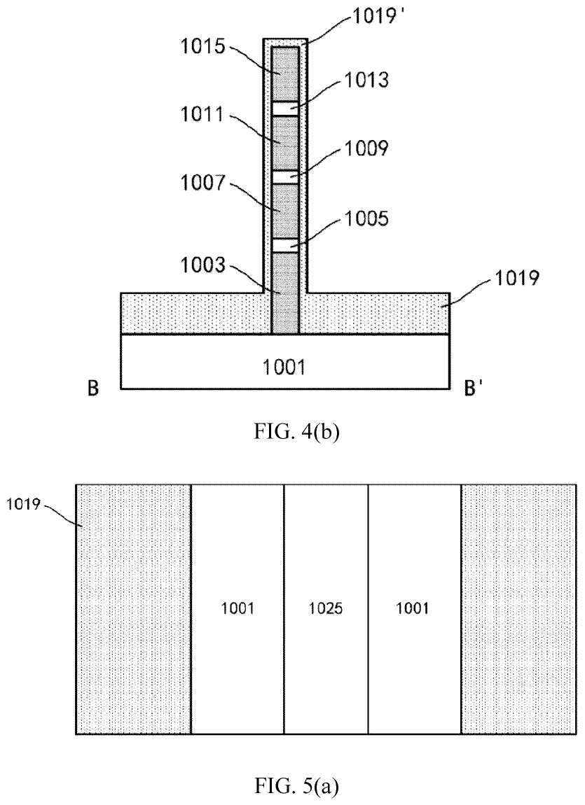

For the purpose of electrical isolation, as shown in FIG. 4(a) and FIG. 4(b), an isolation portion 1019, such as a Shallow Trench Isolation (STI), may be formed on the substrate 1001. For example, the STI 1019 may be formed by depositing an oxide (e.g., silicon oxide) on the substrate, performing a planarization process such as Chemical Mechanical Polishing (CMP) on the deposited oxide, and etching back the planarized oxide by, for example, a wet etching or a vapor phase etching or a dry etching. In addition, a thin etch stop layer 1019′ (e.g., with a thickness in a range of about 1 nm to 5 nm) may be formed on a surface of the semiconductor layer that has been patterned into a nanowire/nanosheet form on the substrate 1001 by, for example, deposition. Here, the etch stop layer 1019′ may also include an oxide, and may be shown as a thin layer integral with the STI 1019.

As described above, the gate defining layers 1007, 1011, 1015 are located on upper and lower sides of the nanowire/nanosheet defining layers 1009, 1013. In order to form the gate-all-around, another gate defining layer may be formed on left and right sides in an orientation shown in FIG. 4(b). For example, as shown in FIG. 5(a) and FIG. 5(b), a gate defining layer 1021 may be formed on the STI 1019 and the etch stop layer 1019′. For example, the gate defining layer 1021 may be formed by depositing substantially the same material as or similar material to that of the gate defining layers 1007, 1011, 1015 (thereby having substantially the same or similar etching selectivity, so as to be processed together), and performing a planarization processing such as CMP on the deposited material. In the example, the gate defining layer 1021 may include SiGe with an atomic percentage of Ge substantially the same as or similar to that of the gate defining layers 1007, 1011, 1015.

A hard mask layer 1023 may be formed on the gate defining layer 1021 by, for example, deposition, to facilitate patterning. For example, the hard mask layer 1023 may include a nitride (e.g., silicon nitride).

The gate defining layers 1007, 1011, 1015, 1021 may be patterned as a dummy gate extending in a direction (e.g., a vertical direction in FIG. 5(a), a direction perpendicular to a paper surface in FIG. 5(b)) intersecting (e.g., perpendicular to) an extension direction (e.g., a horizontal direction in FIG. 5(a) and FIG. 5(b)) of the preliminary nanowire/nanosheet. For example, a photoresist 1025 may be formed on the hard mask layer 1023, and the photoresist 1025 may be patterned into a strip shape extending in the direction by photolithography. Then, the layers between the STIs 1019 on the substrate 1001 may be selectively etched in sequence by, for example, RIE, with the photoresist 1025 as a mask, and the etching may stop at the substrate 1001. As a result, the nanowire/nanosheet defining layers 1009, 1013 are formed as nanowires or nanosheets subsequently used to provide channels (the nanowire/nanosheet defining layers 1009, 1013 are referred to as nanowires/nanosheets 1009, 1013 below), and are surrounded by the gate defining layers 1007, 1011, 1015, 1021 (which may be collectively referred to as “dummy gate”). The nanowires/nanosheets 1009, 1013 may be self-aligned with the dummy gate. After that, the photoresist 1025 may be removed.

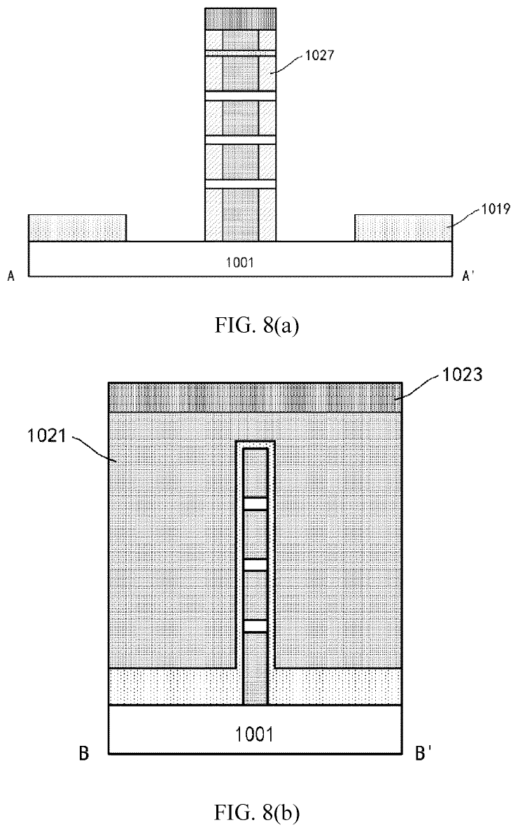

In addition, as shown in FIG. 5(b), the surface of the substrate 1001 on both sides of the dummy gate is exposed, and the exposed surface may facilitate a subsequent growth of the source/drain layers. In addition, the STI 1019 may adjoin the isolation portion defining layer 1003 on opposite sides of the isolation portion defining layer 1003 in an extension direction (a direction perpendicular to the paper surface in the drawing) of the dummy gate, and may extend in self-alignment with the dummy gate (referring to FIG. 8(b)).

In consideration of a limitation of a gate space and an isolation between the gate and the source/drain, a spacer may be formed on a sidewall of the dummy gate. In order to ensure identical gate lengths above and below the nanowires/nanosheets 1009, 1013, the spacer may be formed by using a self-alignment technology. For example, as shown in FIG. 6, the gate defining layers 1007, 1011, 1015, 1021 (SiGe in the example) may be selectively etched relative to the nanowires/nanosheets 1009, 1013 (Si in the example), so that sidewalls of the gate defining layers 1007, 1011, 1015, 1021 are recessed inward by a certain depth in a range of, for example, about 3 nm to 25 nm, relative to a sidewall of the hard mask layer 1023 or sidewalls of the nanowires/nanosheets 1009, 1013. Preferably, recessed depths of the gate defining layers 1007, 1011, 1015, 1021 are substantially identical to each other, and recessed depths at left and right sides are substantially identical to each other. For example, a good etch control may be achieved by using an Atomic Layer Etching (ALE). In the example, the isolation portion defining layer 1003 may also include SiGe, and therefore may also be recessed by substantially the same depth. Accordingly, corresponding sidewalls of the etched gate defining layers 1007, 1011, 1015, 1021 (and isolation portion defining layer 1003) may be substantially coplanar.

A spacer may be formed in the recess thus formed. According to embodiments, in order to optimize a device performance, the spacer may be formed by using a ferroelectric material or a negative capacitance material. The ferroelectric material is generally in one of two polarization states, such as an upward polarization or a downward polarization. However, under some special conditions (a special matching of capacitances), the ferroelectric material may be stabilized between the two polarization states, that is, the so-called negative capacitance state. The ferroelectric material includes, for example, an Hf oxide containing Zr, Si and/or Al, such as HfZrO.

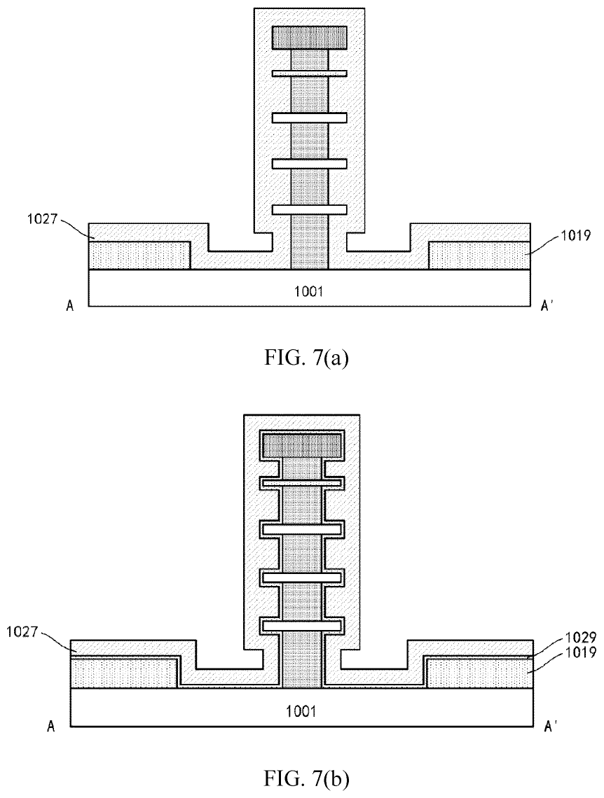

According to an embodiment, as shown in FIG. 7(a), a ferroelectric or negative capacitance material layer 1027 of a certain thickness may be formed on the substrate 1001 by, for example, deposition. A thickness of the deposited ferroelectric or negative capacitance material layer 1027 may be in a range of, for example, about 3 nm to 30 nm, which is sufficient to fill the above-mentioned recess. According to another embodiment, as shown in FIG. 7(b), a dielectric layer 1029 may be formed in a substantially conformal manner before forming the ferroelectric or negative capacitance material layer 1027. For example, the dielectric layer 1029 may include an oxide or a high-k dielectric such as HfO₂.

After that, as shown in FIG. 8(a) and FIG. 8(b), a lateral extension of the dielectric material layer 1027 may be removed by, for example, RIF in the vertical direction, and a vertical extension (including a portion below the hard mask layer 1023) of the dielectric material layer 1027 may be left, so that a spacer 1027 may be formed. A sidewall of the spacer 1027 may be substantially coplanar with the sidewall of the hard mask layer 1023 (and the sidewalls of the nanowires/nanosheets 1009, 1013).

In addition, FIG. 9(a) shows an example of a spacer formed in FIG. 7(b). It can be seen that the dielectric layer 1029 is between the spacer 1027 of the ferroelectric or negative capacitance material and the dummy gate. A total capacitance between the gate and the source/drain may be adjusted by a material selection and a thickness setting of the dielectric layer 1029. In the case, the dielectric layer 1029 is also called a spacer of the dummy gate. Alternatively, the dielectric layer 1029 may be replaced with the ferroelectric or negative capacitance material layer, and the spacer 1027 may be replaced with a conventional dielectric spacer. Alternatively, the spacer may be formed as a multi-layer configuration, one or more of which are ferroelectric or negative capacitance materials, and the rest of which are conventional dielectric materials.

In addition, FIG. 9(b) shows an example of a potential equalization layer 1031 further formed between the spacer 1027 and the dielectric layer 1029. The potential equalization layer 1031 may enable potentials to be substantially evenly distributed on a surface of the spacer 1027. For example, the potential equalization layer 1031 may include a conductive layer such as a metal or an alloy, and the metal or the alloy may include at least one element selected from Ti, Ru, Co or Ta, such as TiN, Co, Ru, TaN, etc., with a thickness in a range of about 0.5 nm to 2 nm. For other spacer configurations described in combination with FIG. 9(a), the potential equalization layer may also be used.

In addition, when the conductive layer such as the potential equalization layer is formed on a peripheral sidewall of the dummy gate, as shown in FIG. 9(c), the dummy gate may be cut off in an extension direction (e.g., a vertical direction in FIG. 9(c)) of the dummy gate to avoid a possible short circuit between the source and the drain caused by an existence of the conductive layer as shown in a dotted line in FIG. 9(c).

The case shown in FIG. 8(a) and FIG. 8(b) will be described below as an example.

As shown in FIG. 8(a) and FIG. 8(b), the sidewall of each nanowire/nanosheet is exposed to the outside (and may be substantially coplanar with the sidewall of the hard mask layer) in a direction (a horizontal direction in FIG. 8(a)) intersecting (e.g., perpendicular to) the extension direction (a direction perpendicular to a paper surface in FIG. 8(a)) of the dummy gate. As shown in FIG. 10, a source/drain layer 1033 may be formed by, for example, selective epitaxial growth, with the exposed sidewall of the nanowire/nanosheet and the exposed surface of the substrate 1001 as a seed. The source/drain layer 1033 may be formed to adjoin the exposed sidewalls of all nanowires/nanosheets. The source/drain layer 1033 may include various suitable semiconductor materials. In order to enhance a device performance, the source/drain layer 1033 may include a semiconductor material having a lattice constant different from that of the nanowire/nanosheet, so as to apply a stress to the nanowire/nanosheet in which a channel region is to be formed. For example, for an n-type device, the source/drain layer 1033 may include Si: C (an atomic percentage of C may be in a range of, for example, about 0.1% to 3%) to apply a tensile stress; for a p-type device, the source/drain layer 1033 may include SiGe (an atomic percentage of Ge may be in a range of, for example, about 20% to 80%) to apply a compressive stress. In addition, the source/drain layer 1033 may be doped to a desired conductive type (n-type doping for the n-type device and p-type doping for the p-type device) by, for example, in situ doping or ion implantation.

In embodiments shown in FIG. 10, a source/drain layer grown from the sidewall of the nanowire/nanosheet adjoins a source/drain layer grown from the surface of the substrate 1001, which may facilitate a heat dissipation or an enhancement of a stress in the channel so as to improve the device performance. In addition, in other embodiments of the present disclosure, the source/drain layer grown from the sidewall of the nanowire/nanosheet is spaced apart from the source/drain layer grown from the surface of the substrate 1001.

Next, a replacement gate process may be performed.

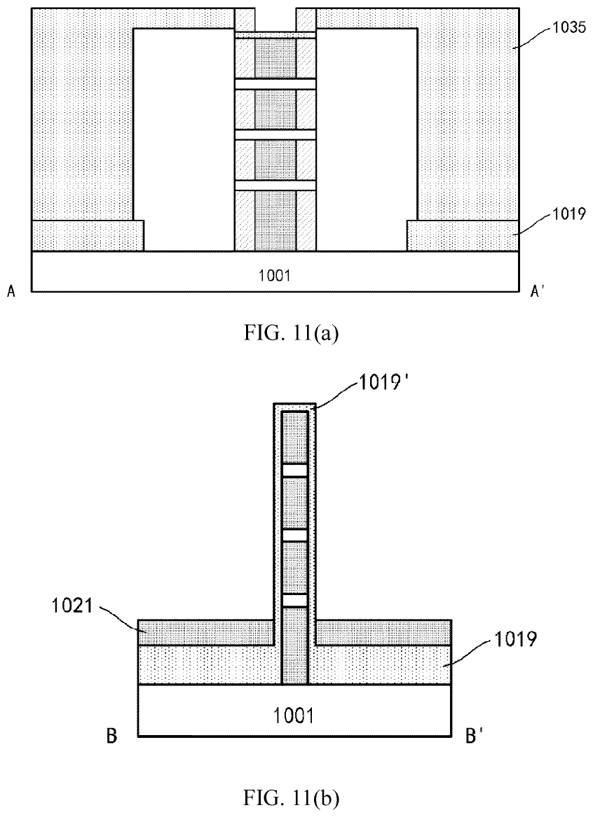

For example, as shown in FIG. 11(a) and FIG. 11(b), an interlayer dielectric layer 1035 may be formed on the substrate 1001. For example, the interlayer dielectric layer 1035 may be formed by depositing an oxide, performing a planarization process such as CMP on the deposited oxide, and etching back the planarized oxide. The interlayer dielectric layer 1035 may be formed to expose the hard mask layer 1023 while covering the source/drain layer 1033. After that, the hard mask layer 1023 may be removed by selective etching, so as to expose the gate defining layer 1021.

In order to perform the replacement gate process, the dummy gate, i.e., all the gate defining layers, need be removed and replaced with the gate stack. Here, in consideration of a formation of an isolation portion below the lowermost gate defining layer 1007, the isolation portion defining layer 1003 may be processed first. Specifically, the isolation portion defining layer 1003 may be replaced with the isolation portion. To this end, a processing channel to the isolation portion defining layer 1003 may be formed.

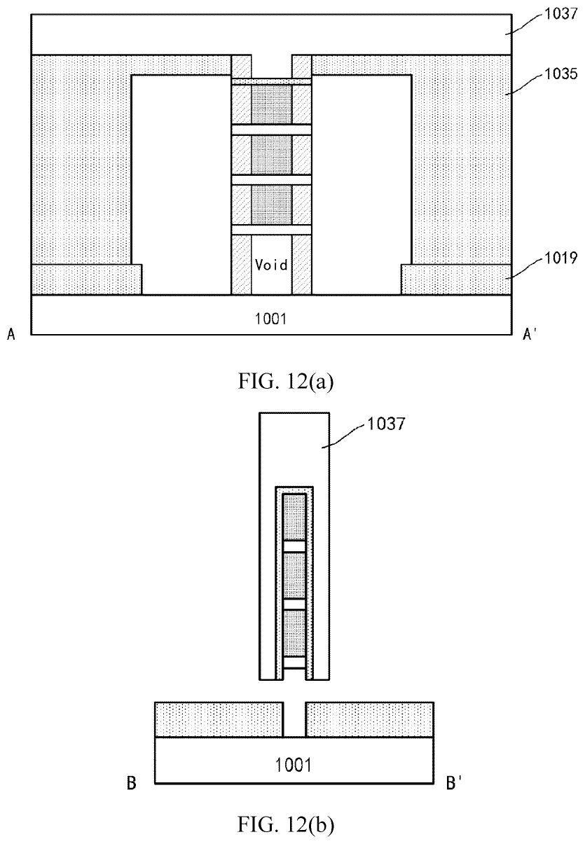

For example, a height of a top surface of the gate defining layer 1021 may be reduced to be lower than a height of a top surface of the isolation portion defining layer 1003 by selective etching, but a certain thickness of the gate defining layer 1021 still remains, so that a mask layer subsequently formed (referring to 1037 in FIG. 12(a) and FIG. 12(b)) may mask all the gate defining layers 1007, 1011, 1015 above the top surface of the isolation portion defining layer 1003 while exposing the isolation portion defining layer 1003. For example, an etching depth may be controlled well by using ALE. Here, other gate defining layers 1007, 1011, 1015 may not be affected due to an existence of the etch stop layer 1019′.

Then, as shown in FIG. 12(a) and FIG. 12(b), a mask layer such as a photoresist 1037 may be formed on the gate defining layer 1021. The photoresist 1037 may be patterned by photolithography into a strip shape extending in an extension direction of the nanowire/nanosheet, and may mask outer surfaces of the nanowire/nanosheet and the gate defining layers 1007, 1011, 1015 (with the etch stop layer 1019′ therebetween). Due to an existence of the gate defining layer 1021, part of a surface of the isolation portion defining layer 1003 is not masked by the photoresist 1037. After that, a selective etching may be performed to sequentially remove the gate defining layer 1021, a portion of the etch stop layer 1019′ exposed by a removal of the gate defining layer 1021, and the isolation portion defining layer 1003 exposed by a removal of the portion of the etch stop layer 1019′. Therefore, a void is formed below the etch stop layer 1005. Since the isolation portion defining layer 1003 and the nanowires/nanosheets and the gate defining layers that are located above are defined by the same hard mask layer, the isolation portion defining layer 1003 may be aligned with the nanowires/nanosheets and the gate defining layers that are located above in the vertical direction. Accordingly, the void formed by the removal of the isolation portion defining layer 1003 may be self-aligned with the nanowires/nanosheets and the gate defining layers that are located above. After that, the photoresist 1037 may be removed.

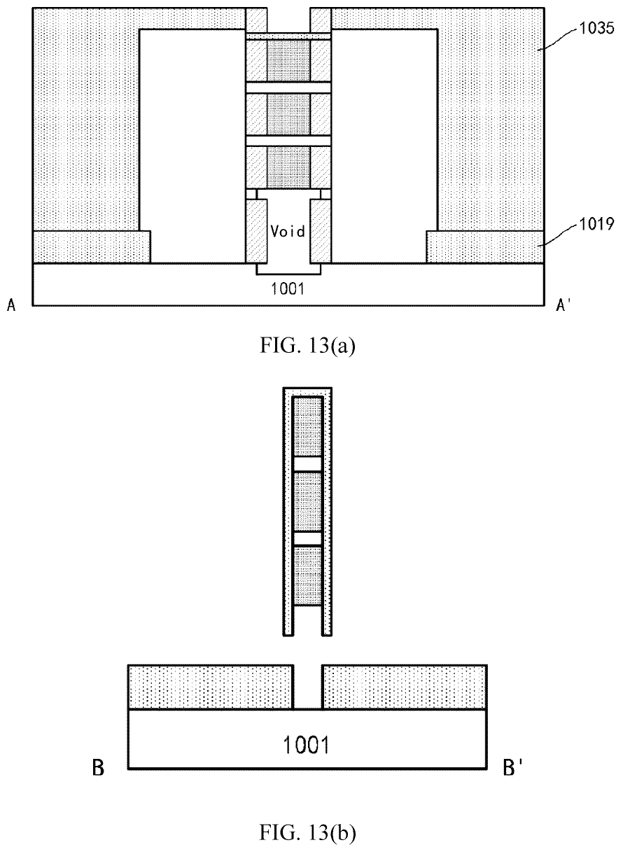

In the example, the etch stop layer 1005 also includes a semiconductor material and is connected between opposite source/drain layers, which may result in a leakage path. To this end, as shown in FIG. 13(a) and FIG. 13(b), the etch stop layer 1005 may be cut off between the opposite source/drain layers by selective etching, such as wet etching using a TMAH solution. End portions of the etch stop layer 1005 may be remained so as not to affect the source/drain layers on both sides. Moreover, the remained end portions of the etch stop layer 1005 may not extend to an inner side of the spacer so as not to be in contact with the gate defining layer (which is subsequently replaced with the gate stack) on the inner side of the spacer. That is, an inner sidewall of the remained etch stop layer 1005 may be recessed relative to an inner sidewall of the spacer. As the etching starts from the middle, opposite ends of the remained etch stop layer 1005 may be substantially symmetrical. In addition, in the example, both the etch stop layer 1005 and the substrate 1001 include silicon, so that the substrate 1001 may also be partially etched away. Therefore, a void between the lowermost gate defining layer 1007 and the substrate 1001 may be enlarged, and the void may still be kept substantially aligned with the nanowires/nanosheets and the gate defining layers that are located above.

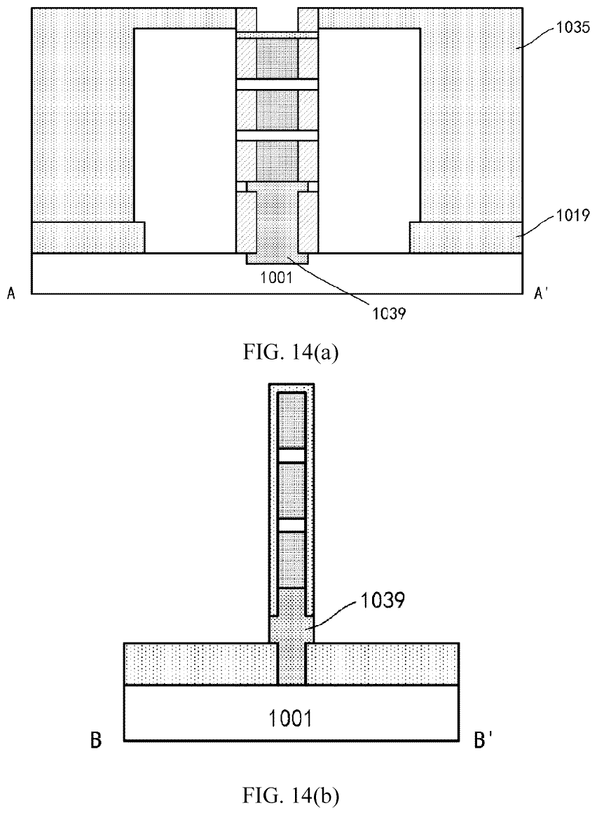

As shown in FIG. 14(a) and FIG. 14(b), the void thus formed may be filled with a dielectric material, such as a low-k dielectric material, to form an isolation portion 1039. A material of the isolation portion 1039, such as a nitrogen oxide (e.g., silicon oxynitride), may have etching selectivity relative to the STI 1019. For example, the isolation portion 1039 may be formed by depositing a sufficient nitrogen oxide on the substrate 1001 and etching back the deposited nitrogen oxide by, for example, RIE. The isolation portion 1039 thus formed may be self-aligned with the nanowires/nanosheets and the gate defining layers that are located above.

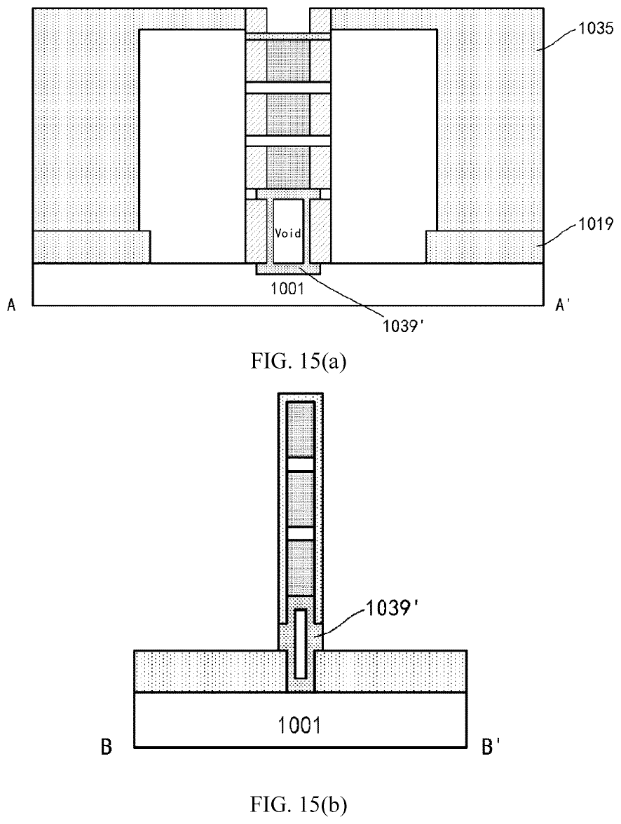

According to other embodiments, as shown in FIGS. 15(a) and 15(b), when the dielectric material is deposited, an isolation portion 1039′ may form a hollow structure due to a space limitation of the above-mentioned void. In this case, a dielectric constant of the isolation portion 1039′ may be further reduced.

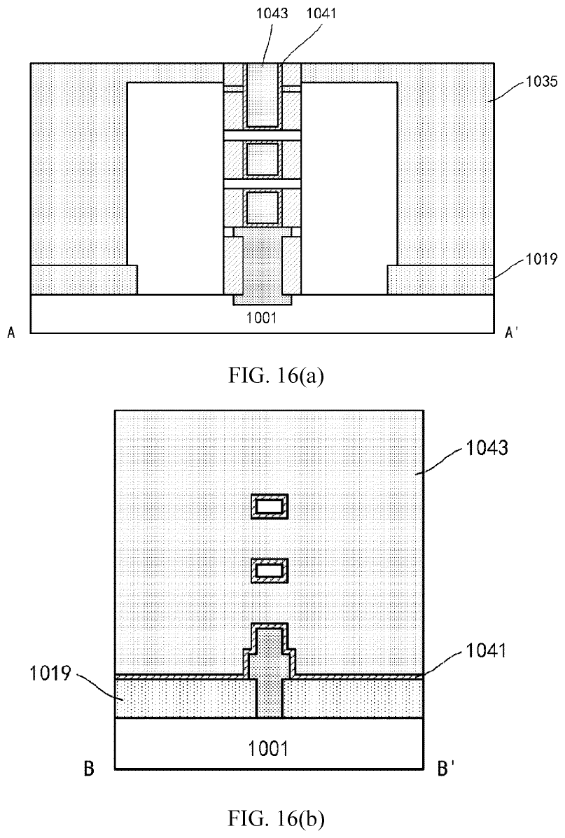

Next, as shown in FIG. 16(a) and FIG. 16(b), the thin etch stop layer 1019′ may be removed by selective etching, so as to expose the gate defining layer, and the gate defining layer may be further removed by selective etching. Thus, a gate trench (corresponding to a space originally occupied by each gate defining layer) may be formed above the STI 1019 and the isolation portion 1039 on the inner side of the spacer 1027. A gate dielectric layer 1041 and a gate electrode 1043 may be sequentially formed in the gate trench thus formed, so as to obtain a final gate stack. For example, the gate dielectric layer 1041 may include a high-k gate dielectric such as HfO₂ with a thickness in a range of about 2 nm to 10 nm; the gate electrode 1043 may include a work function adjustment layer such as TiN, TiAlN, TaN, etc., and a gate conductor layer such as W, Co, Ru, etc. Before the high-k gate dielectric is formed, an interface layer, for example, an oxide formed by an oxidation process or deposition such as Atomic Layer Deposition (ALD) with a thickness in a range of about 0.3 nm to 2 nm, may be formed.

As shown in FIG. 16(a) and FIG. 16(b), the nanowire/nanosheet device according to embodiments may include the nanowires/nanosheets 1009, 1013 (the number thereof may be less or more) spaced apart from the substrate 1001 and the gate electrode 1043 surrounding the nanowires/nanosheets 1009, 1013. The gate electrode 1043 is arranged opposite to the nanowires/nanosheets 1009, 1013 via the gate dielectric layer 1041. The spacer 1027 formed by the ferroelectric or negative capacitance material is formed on a sidewall of the gate electrode 1043 (which may be referred to as a “gate spacer”). As described above, the ferroelectric or negative capacitance material may be switched between two polarization states or in a negative capacitive state. According to different states of the ferroelectric or negative capacitance material, the device may have different performances, such as a threshold voltage (Vt), a Drain Induced Barrier Lowering (DIBL), a Subthreshold Swing (SS), etc. When the ferroelectric or negative capacitance material is in the negative capacitive state, a value of a capacitance between the gate electrode 1043 and the source/drain layer may be less than zero.

When the ferroelectric material is switched between different polarization states, data may be stored according to different device states, such as Vt, caused by the different polarization states, so that the device may be used in a memory device. In addition, when the ferroelectric material is stabilized between two polarization states (in the negative capacitance state), a resulting negative capacitance value may reduce an overlapping capacitance in the device and thus improve the device performance. Accordingly, the device may be used in a logic device. Therefore, the nanowire/nanosheet device according to the present disclosure may be used for both the memory device and the logic device.

The nanowire/nanosheet device may further include the isolation portion 1039. As described above, the isolation portion 1039 may be self-aligned with the nanowires/nanosheets 1009, 1013 or the gate electrode. The spacer 1027 of the ferroelectric or negative capacitance material may also be formed on a sidewall of the isolation portion 1039. Therefore, a capacitance between the gate electrode 1043 and the substrate 1001 may be reduced. Specifically, a parallel connection of a (positive) capacitance formed by the isolation portion 1039 and a (negative) capacitance formed by the spacer 1027 may exist between the lowermost gate electrode 1043 and the substrate 1001. Therefore, a total capacitance of the positive capacitance and the negative capacitance may be reduced relative to a case that all between the lowermost gate electrode 1043 and the substrate 1001 are conventional dielectrics.

Inner sidewalls of the spacer 1027 may be substantially coplanar in the vertical direction, so as to provide a same gate length. In addition, outer sidewalls of the gate spacer 1027 may also be coplanar in the vertical direction, and may be coplanar with the sidewalls of the nanowires/nanosheets 1009, 1013.

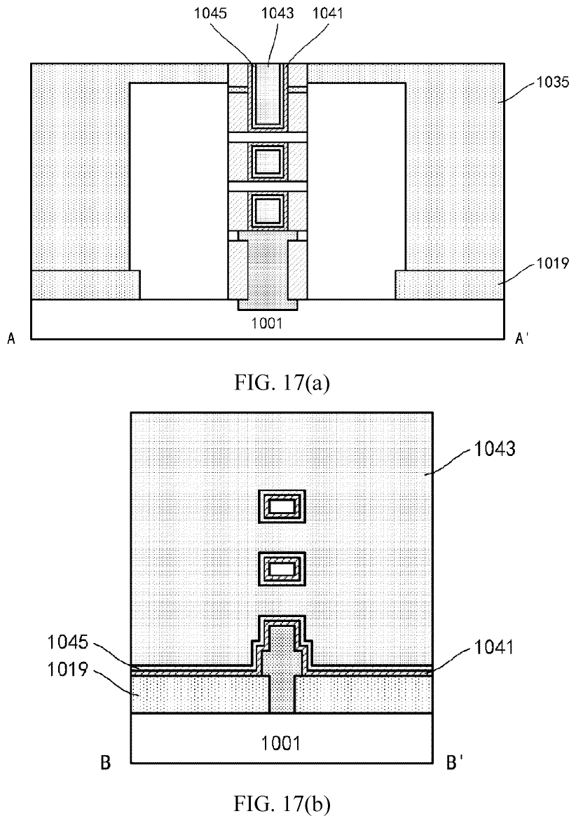

According to other embodiments of the present disclosure, as shown in FIG. 17(a) and FIG. 17(b), a ferroelectric or negative capacitance material layer 1045 may further be inserted between the gate dielectric layer 1041 and the gate electrode 1043 to adjust the capacitance value and the device performance. For example, the ferroelectric or negative capacitance material layer 1045 may include HfZrO with a thickness in a range of about 2 nm to 15 nm. Alternatively, the ferroelectric or negative capacitance material layer 1045 may be formed first, and then the gate dielectric layer 1041 and the gate electrode 1043 may be formed. Therefore, the gate dielectric layer 1041 is between the ferroelectric or negative capacitance material layer 1045 and the gate electrode 1043. In the case, the spacer 1027 is not limited to including the ferroelectric material or negative capacitance material, and may include a conventional dielectric material such as nitride.

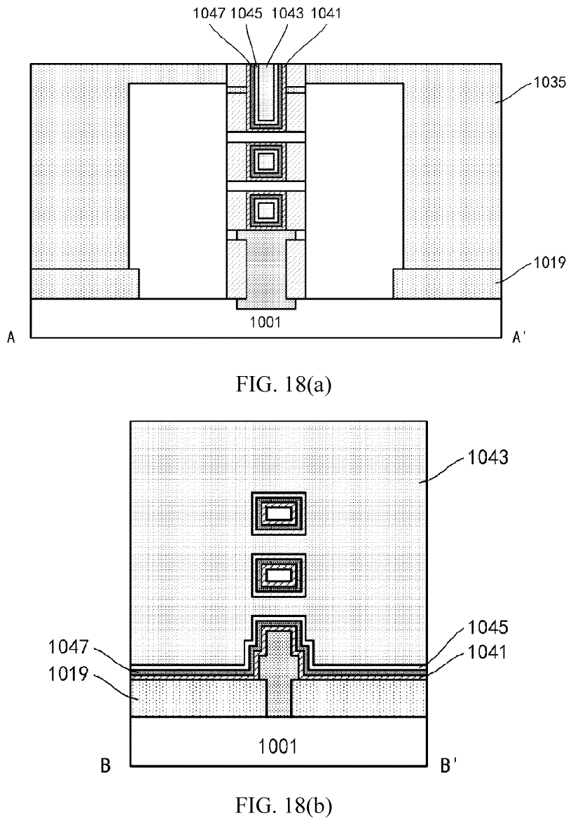

According to embodiments of the present disclosure, as shown in FIG. 18(a) and FIG. 18(b), a potential equalization layer 1047 may be formed on a surface of the ferroelectric or negative capacitance material layer 1045 to equalize a potential. In the example, the potential equalization layer 1047 is between the gate dielectric layer 1041 and the ferroelectric or negative capacitance material layer 1045. For example, the potential equalization layer 1047 may include a conductive layer such as a metal or an alloy, and the metal or the alloy may include at least one element selected from Ti, Ru, Co or Ta, such as TiN, Co, Ru, TaN, etc., with a thickness in a range of about 0.5 nm to 2 nm. Alternatively, the gate dielectric layer 1041 is between the ferroelectric or negative capacitance material layer 1045 and the gate electrode 1043, the potential equalization layer 1047 may be between the ferroelectric or negative capacitance material layer 1045 and the gate dielectric layer 1041.

The above-mentioned description in combination with FIG. 16(a) to FIG. 18(b) also applies to the configurations described with reference to FIG. 9(a) to FIG. 9(c).

The nanowire/nanosheet device according to embodiments of the present disclosure may be applied to various electronic apparatuses. For example, an Integrated Circuit (IC) may be formed based on the nanowire/nanosheet device, and thus an electronic apparatus may be constructed. Accordingly, the present disclosure further provides an electronic apparatus including the nanowire/nanosheet device as described above. The electronic apparatus may further include a display screen cooperating with the integrated circuit, a wireless transceiver cooperating with the integrated circuit, and other components. For example, the electronic apparatus may include a smart phone, a computer, a tablet computer, a wearable intelligent apparatus, an artificial intelligence apparatus, and a mobile power supply, etc.

According to embodiments of the present disclosure, a method of manufacturing a System on Chip (SoC) is further provided. The method may include the method as described above. In particular, various devices may be integrated on the chip, at least some of which are manufactured according to the method of the present disclosure.

In the above-mentioned descriptions, technical details such as patterning and etching of each layer have not been described in detail. However, those skilled in the art should understand that various technical means may be used to form layers, regions, etc. of desired shapes. In addition, in order to form the same structure, those skilled in the art may further design a method that is not completely the same as the method as described above. In addition, although the embodiments are described above separately, this does not mean that the measures in the embodiments may not be advantageously used in combination.

Embodiments of the present disclosure have been described above. However, these embodiments are for illustrative purposes only, and are not used to limit the scope of the present disclosure. The scope of the present disclosure is defined by the appended claims and their equivalents. Without departing from the scope of the present disclosure, those skilled in the art may make various substitutions and modifications, and these substitutions and modifications should all fall within the scope of the present disclosure.

What is claimed is:

1. A nanowire/nanosheet device, comprising:
a substrate;
a nanowire/nanosheet on the substrate and spaced apart from a surface of the substrate;
a gate electrode surrounding the nanowire/nanosheet;
a ferroelectric or negative capacitance material layer formed on a sidewall of the gate electrode; and
source/drain layers at opposite ends of the nanowire/nanosheet and adjoining the nanowire/nanosheet.

2. The nanowire/nanosheet device according to claim 1, wherein the nanowire/nanosheet device has a threshold voltage that varies according to a state of the ferroelectric or negative capacitance material layer.

3. The nanowire/nanosheet device according to claim 1, wherein a value of a capacitance between the gate electrode and the source/drain layer is less than zero.

4. The nanowire/nanosheet device according to claim 1, wherein the ferroelectric or negative capacitance material layer is a gate spacer of the nanowire/nanosheet device.

5. The nanowire/nanosheet device according to claim 4, wherein the ferroelectric or negative capacitance material layer extends along substantially an entire height of the sidewall of the gate electrode.

6. The nanowire/nanosheet device according to claim 4, further comprising:
a gate dielectric layer between the gate electrode and the nanowire/nanosheet and between the gate electrode and the ferroelectric or negative capacitance material layer,
wherein the ferroelectric or negative capacitance material layer extends along substantially an entire height of a sidewall of the gate dielectric layer.

7. The nanowire/nanosheet device according to claim 4, further comprising:
a potential equalization layer formed on a sidewall of the ferroelectric or negative capacitance material layer facing the gate electrode and on upper and lower surfaces of the ferroelectric or negative capacitance material layer.

8. The nanowire/nanosheet device according to claim 7, further comprising:
a dielectric layer formed on the sidewall of the ferroelectric or negative capacitance material layer facing the gate electrode and on the upper and lower surfaces of the ferroelectric or negative capacitance material layer, wherein the potential equalization layer is between the dielectric layer and the ferroelectric or negative capacitance material layer.

9. The nanowire/nanosheet device according to claim 1, further comprising:
a gate dielectric layer formed on the sidewall of the gate electrode and a surface of the gate electrode facing the nanowire/nanosheet,
wherein the ferroelectric or negative capacitance material layer is between the gate electrode and the gate dielectric layer, or the gate dielectric layer is between the ferroelectric or negative capacitance material layer and the gate electrode.

10. The nanowire/nanosheet device according to claim 9, further comprising:
a potential equalization layer between the ferroelectric or negative capacitance material layer and the gate dielectric layer.

11. The nanowire/nanosheet device according to claim 9, further comprising:
a gate spacer formed on the sidewall of the gate electrode, wherein the ferroelectric or negative capacitance material layer, the gate dielectric layer and the gate electrode are located in a space defined by the gate spacer.

12. The nanowire/nanosheet device according to claim 11, wherein the gate spacer comprises a ferroelectric or negative capacitance material.

13. The nanowire/nanosheet device according to claim 4, wherein a sidewall of the gate spacer facing away from the gate electrode is substantially coplanar in a vertical direction with a sidewall of the nanowire/nanosheet.

14. The nanowire/nanosheet device according to claim 4, wherein sidewalls of the gate spacer facing the gate electrode are substantially coplanar with each other in a vertical direction.

15. The nanowire/nanosheet device according to claim 4, further comprising:
an isolation portion between a surface of the gate electrode closest to the substrate and the substrate, wherein the isolation portion is self-aligned with the nanowire/nanosheet.

16. The nanowire/nanosheet device according to claim 15, wherein the gate spacer is further formed on a sidewall of the isolation portion, wherein the isolation portion further extends to a top surface of a portion of the gate spacer on the sidewall of the isolation portion.

17. The nanowire/nanosheet device according to claim 16, wherein a spacing distance between the portion of the gate spacer on the sidewall of the isolation portion and an another portion of the gate spacer closest to the portion of the gate spacer is substantially uniform in a vertical direction.

18. The nanowire/nanosheet device according to claim 16, further comprising: a semiconductor material layer between the portion of the gate spacer on the sidewall of the isolation portion and an another portion of the gate spacer closest to the portion of the gate spacer, wherein the semiconductor material layer is on an outer side of the isolation portion.

19. The nanowire/nanosheet device according to claim 15, wherein the isolation portion has a hollow structure.

20. The nanowire/nanosheet device according to claim 7, wherein the potential equalization layer comprises a metal or an alloy.

21. The nanowire/nanosheet device according to claim 20, wherein the metal or the alloy comprises at least one element selected from Ti, Ru, Co or Ta.

22. The nanowire/nanosheet device according to claim 1, wherein a plurality of nanowires/nanosheets are provided, and the nanowires/nanosheets extend substantially parallel to each other, and the nanowires/nanosheets are substantially aligned with each other in a vertical direction.

23. The nanowire/nanosheet device according to claim 1, the ferroelectric or negative capacitance material comprises an Hf oxide containing Zr, Si and/or Al.

24. A method of manufacturing a nanowire/nanosheet device, comprising:
providing, on a substrate, a nanowire/nanosheet spaced apart from a surface of the substrate;
forming, on the substrate, a dummy gate surrounding the nanowire/nanosheet;
forming a spacer on a sidewall of the dummy gate using a ferroelectric or negative capacitance material; and
removing the dummy gate, and forming, on an inner side of the spacer, a gate electrode in a gate trench formed by a removal of the dummy gate.

25. The method according to claim 24, further comprising:
forming a ferroelectric or negative capacitance material layer in the gate trench.

26. A method of manufacturing a nanowire/nanosheet device, comprising:
providing, on a substrate, a nanowire/nanosheet spaced apart from a surface of the substrate;
forming, on the substrate, a dummy gate surrounding the nanowire/nanosheet;
forming a spacer on a sidewall of the dummy gate;
removing the dummy gate, and forming, on an inner side of the spacer, a ferroelectric or negative capacitance material layer in a gate trench formed by a removal of the dummy gate; and
forming a gate electrode in the gate trench formed with the ferroelectric or negative capacitance material layer.

27. The method according to claim 26, wherein the spacer is formed using a ferroelectric or negative capacitance material.

28. The method according to claim 25 or 26, wherein the ferroelectric or negative capacitance material layer is continuously formed along an inner surface of the gate trench.

29. The method according to claim 28, further comprising:
forming a gate dielectric layer along the inner surface of the gate trench, wherein the ferroelectric or negative capacitance material layer is between the gate dielectric layer and the gate electrode, or the gate dielectric layer is between the ferroelectric or negative capacitance material layer and the gate electrode.

30. The method according to claim 29, further comprising:
forming a potential equalization layer between the gate dielectric layer and the ferroelectric or negative capacitance material layer.

31. The method according to claim 24, wherein the providing a nanowire/nanosheet comprises:
forming an isolation portion defining layer on the substrate;
forming, on the isolation portion defining layer, a stack of one or more gate defining layers and one or more nanowire/nanosheet defining layers alternately arranged;
patterning the stack and the isolation portion defining layer as a preliminary nanowire/nanosheet extending in a first direction;
forming another gate defining layer on the substrate to cover the stack and the isolation portion defining layer;
patterning the another gate defining layer into a strip shape extending in a second direction, wherein the second direction intersects the first direction; and
patterning the stack and the isolating portion defining layer into a wire shape or a sheet shape by using the strip-shaped another gate defining layer as a mask, wherein the nanowire/nanosheet defining layer patterned into the wire shape or the sheet shape forms the nanowire/nanosheet.

32. The method according to claim 31, wherein
the forming a dummy gate comprises: selectively etching the isolation portion defining layer and the gate defining layer, so that sidewalls of the isolation portion defining layer and the gate defining layer are recessed inward relative to a sidewall of the nanowire/nanosheet, wherein the gate defining layer forms the dummy gate, and
wherein the forming a spacer comprises: forming the spacer in the recess.

33. The method according to claim 32, further comprising:
forming a dielectric layer along an inner surface of the recess; and
forming a potential equalization layer on the dielectric layer,
wherein the spacer is formed on the potential equalization layer.

34. The method according to claim 32, further comprising:
forming an etch stop layer on the isolation portion defining layer, wherein the stack is formed on the etch stop layer,
wherein the method further comprises: after forming the spacer,
forming, on opposite sides of the nanowire/nanosheet in the first direction, source/drain layers adjoining the nanowire/nanosheet;
removing, by a selective etching, the isolation portion defining layer from opposite sides of the nanowire/nanosheet in the second direction;
removing a middle portion of the etch stop layer by the selective etching; and
filling a dielectric material in a space caused by a removal of the isolation portion defining layer and the middle portion of the etch stop layer, so as to form an isolation portion.

35. The method according to claim 34, wherein the isolation portion has a hollow structure.

36. An electronic apparatus, comprising the nanowire/nanosheet device according to claim 1.

37. The electronic apparatus according to claim 36, comprising a smart phone, a computer, a tablet computer, a wearable intelligent apparatus, an artificial intelligence apparatus, and a mobile power supply.
